(19) United States
(12) Patent Application Publication
(10) Pub. No.: US 2011/0241013 A1
(43) Pub. Date: Oct. 6, 2011

(54) Thin film transistor, method of producing the same and flexible display device including the thin film transistor

(76) Inventors: Sung-Guk An, Yongin-City (KR); Hyung-Sik Kim, Yongin-city (KR); Young-Gu Kim, Yongin-city (KR); Sang-Joon Seo, Yongin-city (KR); Tae-Woong Kim, Yongin-city (KR); Moo-Jin Kim, Yongin-city (KR); Dong-Un Jin, Yongin-city (KR)

(21) Appl. No.: 13/064,535

(22) Filed: Mar. 30, 2011

(30) Foreign Application Priority Data
Mar. 31, 2010 (KR) 10-2010-0029345

(51) Int. Cl. H01L 29/786; H01L 21/336

(52) U.S. Cl. 257/72; 257/347; 438/158; 257/E21.409; 257/E29.273

(57) ABSTRACT

A thin film transistor includes a polymer substrate having a weight loss of 0.95% or less at a temperature in the range of 400 to 600° C. A method of producing the thin film transistor includes forming a polymer substrate by forming a polymer layer and annealing the polymer layer at a temperature in the range of 150 to 550° C. A flexible display device includes the thin film transistor.

### CROSS-REFERENCE TO RELATED APPLICATIONS

This application claims the benefit of Korean Patent Application No. 10-2010-0029345, filed on Mar. 31, 2010, in the Korean Intellectual Property Office, the disclosure of which is incorporated herein in its entirety by reference.

### BACKGROUND

1. Field

Aspects of the present invention relate to a thin film transistor, a method of producing the same, and a flexible display device including the thin film transistor.

2. Description of the Related Art

Research is being conducted into an amorphous silicon thin film transistor for liquid crystal displays used for flexible displays. Research is also being conducted into an amorphous silicon thin film transistor, a low temperature poly-silicon (LTPS) thin film transistor, and a metal oxide thin film transistor that is processed at low temperature for organic light emitting displays.

While liquid crystal displays use voltage induced thin film transistors, organic light emitting displays, including flexible organic light emitting displays, use current induced thin film transistors. Accordingly, a polycrystalline silicon thin film transistor having high charge mobility is typically used for organic light emitting displays. However, outgassing may occur in a conventional polymer substrate during the manufacturing of a polycrystalline silicon thin film transistor due to the plastic characteristics of the polymer and the high temperatures that are typically used. Outgassing may adversely affect thin films deposited on a polymer substrate so as to deteriorate the quality of devices, and outgassed residues may remain in a processing chamber to contaminate the chamber. In particular, materials used to form a substrate for flexible organic light emitting displays typically have a high thermal expansion coefficient and a low thermal resistance, and thus it is difficult to use such materials. Thus, research is being conducted into a metal oxide thin film transistor that may be processed at a relatively low temperature. However, a metal oxide thin film transistor has low reliability, and the quality of a device may deteriorate when the device is manufactured at a temperature that is not sufficiently high.

A polycrystalline silicon thin film transistor has high charge mobility and high reliability. However, since a process of manufacturing a low temperature polycrystalline silicon includes dehydrogenation at a temperature in the range of about 400 to 600° C. after deposition of amorphous silicon, it is difficult to apply the low temperature polycrystalline silicon to a flexible display device using a typical polymer substrate.

In order to efficiently perform the dehydrogenation, a double laser treatment is used. The laser treatment includes dehydrogenation using a laser beam and crystallization using excimer laser annealing (ELA). However, a thin film transistor manufactured using the method described above may have low reliability and surface defects caused by excessive laser treatment even though the polycrystalline silicon has high charge mobility.

Therefore, there is still a need to develop a thin film transistor that is resistant to the high temperatures used for dehydrogenation.

### SUMMARY

Aspects of the present invention relate to a thin film transistor, a method of producing the thin film transistor and a flexible display device including the thin film transistor.

According to an aspect of the present invention, there is provided a thin film transistor including a polymer substrate having a weight loss of 0.95% or less at a temperature in the range of 400 to 600° C., a semiconductor layer, a gate insulating layer, a gate electrode, and a source and drain electrode.

According to a non-limiting aspect, the polymer substrate may have a thermal expansion coefficient in the range of 1 to 50 ppm/° C.

According to a non-limiting aspect, the polymer substrate may include a polyimide-based polymer.

According to a non-limiting aspect, the semiconductor layer may include a polycrystalline silicon layer.

According to another aspect of the present invention, there is provided a method of producing a thin film transistor, the method including: preparing a polymer layer; annealing the polymer layer at a temperature in the range of 150 to 550° C. to form a polymer substrate; forming a semiconductor layer on the polymer substrate; and forming a gate insulating layer, a gate electrode, and a source and drain electrode on the polymer substrate.

According to a non-limiting aspect, the annealing may include annealing the polymer layer at a temperature in the range of 150 to 550° C. for 5 minutes to 5 hours.

According to a non-limiting aspect, the forming the semiconductor layer may include: forming an amorphous silicon layer; dehydrogenating the amorphous silicon layer at a temperature in the range of 420 to 550° C.; and crystallizing the dehydrogenated silicon layer by irradiating a laser beam to the dehydrogenated silicon layer.

According to a non-limiting aspect, the dehydrogenating may reduce the amount of hydrogen in the amorphous silicon layer to a concentration of 10% or less.

According to a non-limiting aspect, the forming the gate insulating layer may be performed using tetraethyl orthosilicate (TEOS) at a temperature in the range of 350 to 450° C.

According to a non-limiting aspect, the method may further include forming a barrier layer after the annealing the polymer layer.

According to another aspect of the present invention, there is provided a flexible display device including: the thin film transistor; and a display diode formed on the thin film transistor to be electrically connected to the thin film transistor.

According to a non-limiting aspect, the display diode may be an organic light emitting diode.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a cross-sectional view of a thin film transistor according to an embodiment of the present invention;

FIGS. 2 to 4 are diagrams illustrating a method of manufacturing a polymer substrate according to an embodiment of the present invention;

FIG. 5 is a graph illustrating weight loss of a polymer substrate with respect to temperature according to an embodiment of the present invention;

FIG. 6 is a graph illustrating weight loss of a polymer substrate with respect to temperature according to a comparative embodiment; and

FIGS. 7 to 9 are cross-sectional views of a flexible display device according to an embodiment of the present invention.

### DETAILED DESCRIPTION

Reference will now be made in detail to the present embodiments of the present invention, examples of which are illustrated in the accompanying drawings, wherein like reference numerals refer to the like elements throughout. The embodiments are described below in order to explain the present invention by referring to the figures.

Hereinafter, aspects of the present invention will now be described more fully with reference to the accompanying drawings, in which exemplary embodiments of the invention are shown. The described aspects of the invention should not be construed as limiting the claims to the embodiments shown.

In the drawings, like reference numerals denote like elements, and the sizes and thicknesses of layers and regions are exaggerated for clarity. It will be understood that when a portion such as a layer, membrane, region, and plate, is referred to as being “on” another portion, it can be directly on the other portion, or intervening portions may also be present therebetween. On the other hand, it will also be understood when a portion is referred to as being “directly on” another portion, it can be directly on the other portion.

A thin film transistor according to an embodiment of the present invention includes a polymer substrate having a weight loss of 0.95% or less at a temperature in the range of 400 to 600° C., a semiconductor layer, a gate insulating layer, a gate electrode, and a source and drain electrode.

The polymer substrate of the thin film transistor has a weight loss of 0.95% or less at a temperature in the range of about 400 to about 600° C. The weight loss is defined as a weight loss of the polymer substrate after annealing per unit weight of the initial polymer substrate measured before the annealing.

If the weight loss is less than 0.95%, the amount of the weight loss of the polymer substrate by an outgassing is less than 0.95% of the initial weight of the polymer substrate, indicating that a small amount of the polymer substrate is lost and that only a small amount of outgassing takes place.

The polymer substrate may have a thermal expansion coefficient in the range of 1 to 50 ppm/° C. The thermal expansion coefficient is shown as a percentage of a ratio of a volume expansion of the polymer substrate by heat to temperature when heat is applied to the polymer substrate at a constant pressure.

When the thermal expansion coefficient is less than 50 ppm/° C., the volume of the polymer substrate increases by less than 50 ppm while the temperature increases by 1° C. by annealing the polymer substrate, indicating that the polymer substrate is not considerably deformed by the annealing.

The polymer substrate may include a polyimide-based polymer. A polyimide-based polymer typically has excellent thermal resistance and high mechanical strength and may be processed at about 550° C. Thus, when a thin film transistor and organic light emitting diode formed on a polymer substrate formed of polyimide are annealed, the polymer substrate may stably function as a substrate of a flexible display device and will not collapse due to weight of the layers of the diodes and the thin film transistor.

The semiconductor layer of the thin film transistor may include a polycrystalline silicon layer. A polycrystalline silicon semiconductor layer has higher electron mobility than an amorphous silicon semiconductor layer in a thin film transistor.

Hereinafter, a method of producing the thin film transistor including the polymer substrate will be described in more detail.

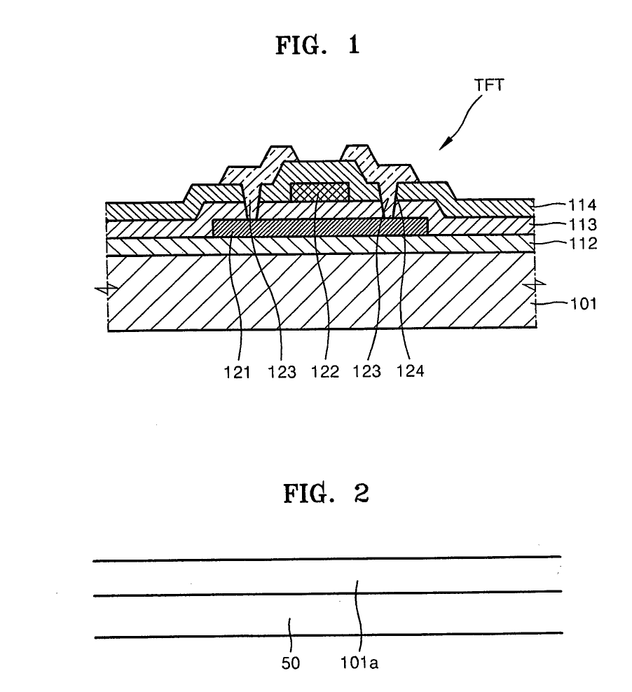

Referring to FIG. 1, a polymer layer is prepared, a polymer substrate 101 is formed by annealing the polymer layer at a temperature in the range of 150 to 550° C., a semiconductor layer 121 is formed on the polymer substrate 101, and a gate insulating layer 113, a gate electrode 122, and source and drain electrodes 123 are formed on the semiconductor layer 121.

The method of producing the polymer substrate 101 will be described in more detail with reference to FIGS. 2 to 4.

Referring to FIG. 2, a polymer layer 101a is formed on a glass plate 50.

The polymer layer 101a may be formed of a polyimide-based polymer. A polyimide-based polymer has sufficient mechanical strength, and thus the polymer layer 101a formed of the polyimide-based polymer is not considerably deformed even when a variety of devices or layers are formed thereon. Specifically, the polymer layer 101a may be formed by coating a polyimide-based polymer resin solution on a glass plate 50.

Even though a thin polymer layer 101a is light and efficiently used for a thin-film display, it is desirable that the thickness of the polymer layer 101a be sufficient for supporting the weight of a diode on the polymer substrate that is formed by annealing the polymer layer 101a. The thickness of the polymer layer 101a may be in the range of 10 to 200 μm. When the glass plate 50 is detached from the polymer layer 101a having a thickness of 10 μm or greater, the polymer substrate formed using the polymer layer 101a may stably sustain the layers of thin film transistors and diodes formed thereon. The polymer layer 101a having a thickness of 200 μm or less is suitable for a thin-film flexible display device.

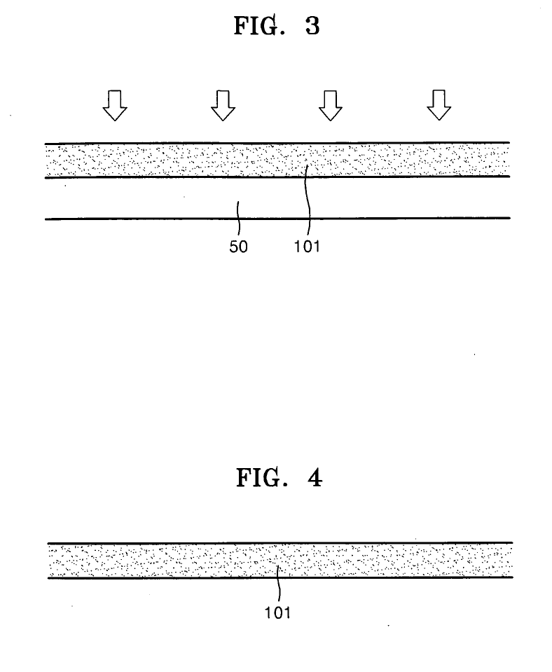

Referring to FIG. 3, the polymer layer 101a is annealed at a temperature of 150° C. or more, for example, in the range of 150 to 550° C., to form a polymer substrate 101. In this regard, the annealing may be performed at a single temperature within the range described above or may be performed while changing the temperature within the range described above.

For example, the polymer layer 101a may be annealed at a temperature in the range of 150 to 550° C. for 5 minutes to 5 hours.

Referring to FIG. 4, the glass plate 50 is removed from the polymer substrate 101. However, when a diode having a thin-film is formed on the polymer substrate 101, the glass plate 50 may be used as a support in order to prevent the polymer substrate 101 from being damaged during the process of forming the diode. In this case, the glass plate 50 may be removed from the polymer substrate 101 after the process is completed.

The weight loss of the annealed polymer substrate 101 may be 0.95% or less at a temperature in the range of 400 to 600° C. Accordingly, the influence of outgassing upon the polymer substrate 101 in subsequent processes may be reduced.

The polymer substrate 101 has a relatively low thermal expansion coefficient that is in the range of 1 to 50 ppm/° C. Thus, since the annealed polymer substrate 101 is not considerably deformed by heat in a subsequent process, the subsequent process may be performed at high temperature without considerably deforming the polymer substrate 101.

Thermal resistance of the annealed polymer substrate 101 described above is evaluated as follows.

A polyimide solution (polymer layer) having a solid content in the range of 5 to 30% is coated on a glass substrate and incrementally annealed while increasing the temperature from room temperature (25° C.) to 500° C. Specifically, the glass substrate on which the polyimide solution is coated is annealed while increasing the temperature from room temperature (25° C.) to 150° C. at a rate of 5° C./min and annealed at 150° C. for 10 minutes. Then, the temperature is raised to 180° C. and the glass substrate is annealed at 180° C. for 10 minutes, and then the temperature is raised to 500° C. and the glass substrate is annealed at 500° C. for 30 minutes.

While heating the annealed polymer substrate from room temperature (25° C.) to 600° C., the amount of the polymer substrate lost by outgassing, i.e., the weight loss, is measured.

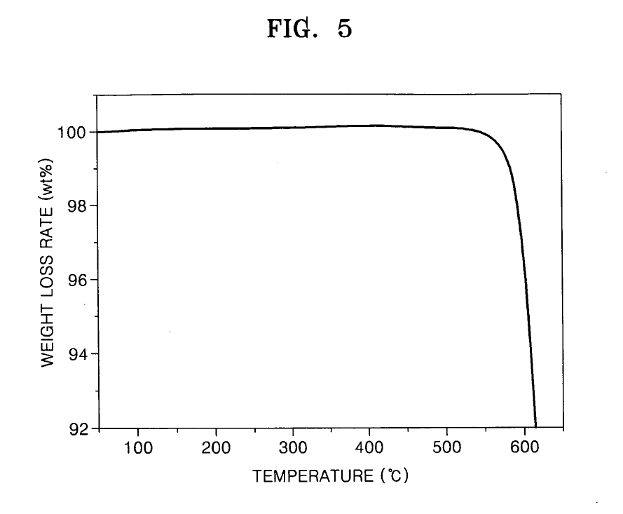

FIG. 5 is a graph illustrating weight loss of a polymer substrate with respect to temperature according to an embodiment of the present invention. Referring to FIG. 5, there is almost no weight loss of the polymer substrate until the temperature reaches about 550° C., and the weight loss of the polymer substrate is less than 1% up to a temperature of about 600° C.

According to a comparative Embodiment, Kapton film, which is commonly used for a polymer substrate in a flexible display device, was evaluated for the amount of the film lost by outgassing, i.e., the weight loss, measured while heating the Kapton film from room temperature (25° C.) to 550° C.

The Kapton film includes a flexible ether linkage so as to have higher flexibility and higher elongation than polyimide which does not include an ether linkage. However, the present application is not limited to these particular characteristics of the Kapton film. Meanwhile, the polyimide which does not include an ether linkage has higher heat resistance and lower heat expansion, which are critical factors with regard to the substrate of thin film transistor. Therefore, it may be preferable to anneal the polyimide which does not include an ether linkage to form a polymer substrate having a weight loss in the range of about 0.000001 to about 0.95% at a temperature in the range of about 400 to about 600° C. In the polyimide structure below, UIP-S is polyimide which does not include an ether linkage and UIP-S is polyimide which includes an ether linkage:

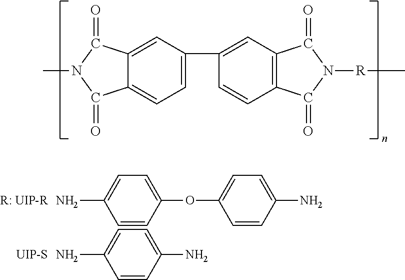

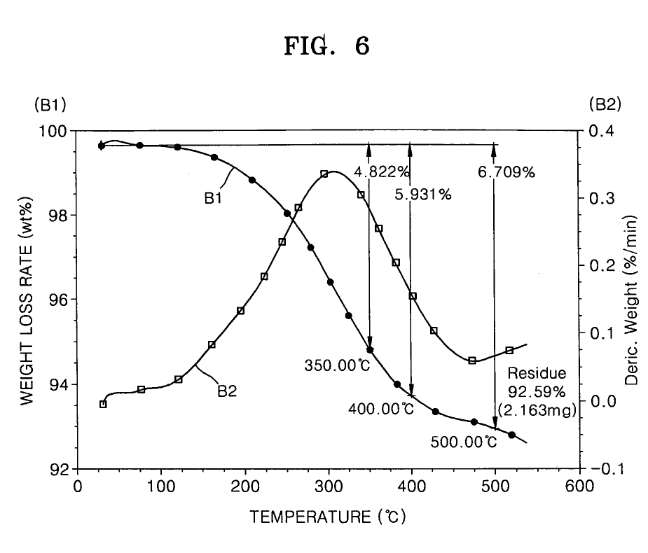

FIG. 6 is a graph illustrating weight loss of the Kapton film substrate with respect to temperature. B1 indicates the change of weight loss with respect to temperature, and B2 indicates the change of weight loss with respect to time. Referring to FIG. 6, the polymer substrate, which is not annealed, has weight loss of about 4.822%, 5.931%, and 6.709% respectively at temperatures of about 350° C., 400° C., and 500° C.

As such, if the polymer substrate is annealed at a temperature ranging from 150 to 550° C., the weight loss of the polymer substrate caused by outgassing may be reduced in subsequent high-temperature processes.

Referring to FIG. 1, a barrier layer 112 may be formed on the annealed polymer substrate 101. The barrier layer 112 may include an inorganic material such as SiOx, SiNx, SiON, AlO, and AlON, or an organic material such as acryl or polyimide. Alternatively, the barrier layer 112 may include the organic material and the inorganic material which are alternately stacked. The barrier layer 112 blocks oxygen and moisture, blocks the diffusion of moisture or impurities generated in the polymer substrate 101, and facilitates the crystallization of the semiconductor by controlling a heat transfer during the crystallization.

A thin film transistor is formed on the barrier layer 112. In FIG. 1, a top gate thin film transistor is shown. However, a bottom gate thin film transistor or any other type of thin film transistor may also be used. Hereinafter, a top gate thin film transistor shown in FIG. 1 will be described for descriptive convenience. To form a top gate transistor, a semiconductor layer 121, a gate insulating layer 113, a gate electrode 122, an interlayer insulating layer 114, a contact hole 124, a source and drain electrode 123, and a protective layer are sequentially formed on the barrier layer 112.

The semiconductor layer 121 may be formed of polycrystalline silicon. In this regard, a part of the semiconductor layer 121 may be doped with impurities.

In general, the semiconductor layer 121 is prepared by forming an amorphous silicon layer and crystallizing the amorphous silicon to form polycrystalline silicon. The crystallization may be conducted using various methods such as rapid thermal annealing (RTA), solid phase crystallization (SPC), excimer laser annealing (ELA), metal induced crystallization (MIC), metal induced lateral crystallization (MILC), or sequential lateral solidification (SLS). Among these methods, the ELA has been used for the crystallization on a mass scale. Thus, in general, ELA is used for crystallization applied to a display device including a flexible organic light emitting diode. When using ELA, it is desirable that the amount of hydrogen in the amorphous silicon layer be equal to or less than about 10%. If the amount of hydrogen in the amorphous silicon layer is greater than 10%, hydrogen is generated when a laser beam is irradiated for the crystallization, so that the quality of the polycrystalline silicon may deteriorate, thereby deteriorating the quality of the thin film transistor. Thus, the amount of hydrogen in the amorphous silicon layer is reduced by annealing. However, in a conventional flexible display, a material used to form the substrate produces a large amount of outgas if a long-term annealing process is performed at a temperature of 400° C. or greater, such that the substrate and equipment are contaminated and bubbles are generated in the substrate. Accordingly, the display may not be easily manufactured. In addition, in order to prepare the thin film transistor including polycrystalline silicon, processes of doping impurities and activating the impurities are carried out. In order to prepare a conventional ELA-based thin film transistor, the activation temperature is typically equal to or greater than 400° C. A substrate for a conventional flexible display cannot stand the high activation temperature. Because of conditions for these dehydrogenization and activation processes, it is very difficult to manufacture a polycrystalline polysilicon thin film transistor by the dehydrogenization and activation processes using the conventional polymer substrate. In order to commercialize a flexible display, a polycrystalline silicon thin film transistor having excellent characteristics is desired. In order to manufacture the polycrystalline silicon thin film transistor, dehydrogenation is also desired.

The thin film transistor according to an embodiment of the present invention includes the polymer substrate having excellent thermal resistance as described above, and thus a dehydrogenation process performed at a temperature in the range of 420 to 550° C. may be applied thereto.

For example, the semiconductor layer 121 may be formed by forming an amorphous silicon layer on the polymer substrate, dehydrogenating the amorphous silicon layer at a temperature in the range of 420 to 550° C., and crystallizing the dehydrogenated silicon layer by irradiating a laser beam to the dehydrogenated silicon layer.

The laser beam used for the dehydrogenation may be a pulse laser beam that does not deliver energy consecutively on the amorphous silicon layer but delivers energy thereon in pulses for a predetermined period of time. The delivering energy for a predetermined period of time is referred to as a shot. In this regard, the amorphous silicon layer is crystallized into a polycrystalline silicon layer by the shots. The laser beam may be moved to a subsequent region after one shot of the laser beam is applied thereto. Alternatively, the laser beam may be moved to a subsequent region after a plurality of shots of the laser beam has been applied thereto. In this regard, the laser beam may be an XeCl excimer laser beam having an energy density in the range of 100 to 1,000 mJ/cm², irradiated for 10 to 40 ns, and having a wavelength of 308 nm.

By the dehydrogenation using the laser beam, the amount of hydrogen in the amorphous silicon layer may be reduced, for example, to 10% or less. If the amount of hydrogen in the amorphous silicon layer is within the range described above, a thin film transistor having excellent characteristics may be prepared since hydrogen is not generated while the laser beam is irradiated for the crystallization.

The gate insulating layer 113 is formed between the semiconductor layer 121 and the gate electrode 122 to insulate therebetween. The gate insulating layer 113 may be formed of a silicon-based insulating material. For example, tetraethyl orthosilicate (TEOS) may be used as a precursor of the silicon-based insulating material. Using TEOS, characteristics and safety of the thin film transistor may be improved, compared to when using silane as the precursor of the silicon-based insulating material.

TEOS may be deposited at a relatively high temperature of 350° C. or greater, for example, in the range of 350 to 450° C. As described above, the polymer substrate 101 has a low outgassing amount at a high temperature of about 400° C. and has low thermal expansion, and thus TEOS, which is typically required to be applied at a high temperature, may be used as a source gas of the gate insulating layer 113. Accordingly, the characteristics of the gate insulating layer 113 may be improved, and safety of the device may be improved by inhibiting deformation of the polymer substrate 101 and reducing the outgassed amount.

The gate electrode 122 may be formed of a variety of conductive materials. For example, the gate electrode 122 may include a material such as Mg, Al, Ni, Cr, Mo, W, MoW, or Au. In this regard, the gate electrode 122 may have various structures, such as, for example, a single layered structure or a multi-layered structure.

The interlayer insulating layer 114 may include a silicon-based insulating material or an insulating organic material. The interlayer insulating layer 114 and the gate insulating layer 113 may be selectively removed to form a contact hole 124 exposing source and drain regions. In addition, source and drain electrodes 123 that have a single layer or a plurality of layers are formed on the interlayer insulating layer 114. The source and drain electrodes 123 may formed of the same material used to form the gate electrode 122 so as to fill the contact hole 124.

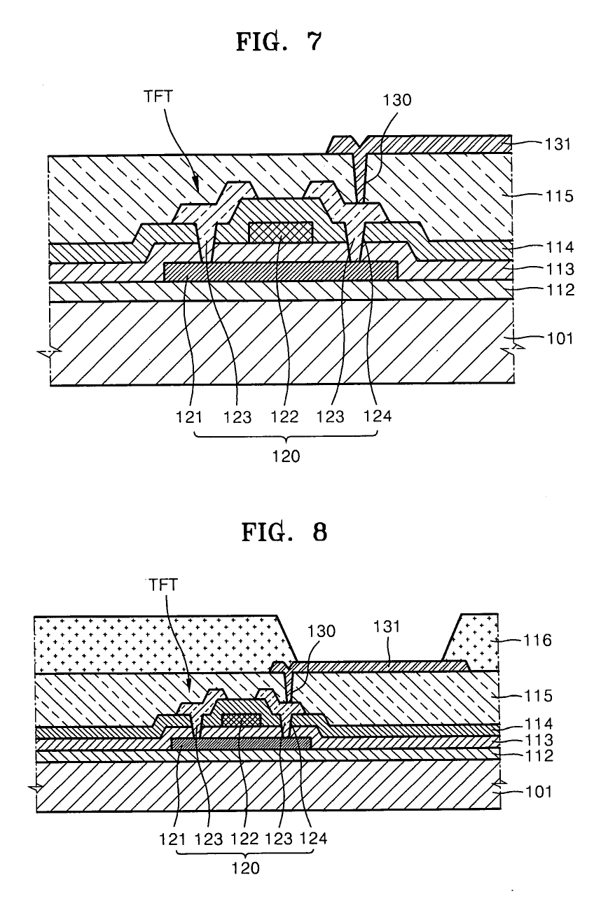

A protective layer (passivation layer and/or planarization layer) 115 (FIG. 7) is formed on the source and drain electrodes 123 to protect the thin film transistor disposed below the protective layer 115 and provide a planarized surface. The protective layer 115 (FIG. 7) may have various shapes. The protective layer 115 may include an organic material such as benzocyclobutene (BCB) or acryl or an inorganic material such as SiNx. The protective layer 115 may also have a single layered, double-layered, or multi-layered structure.

Then, a display diode is formed on the thin film transistor to prepare a flexible display device.

According to an embodiment, the flexible display device includes the thin film transistor having characteristics described above and the display diode that is formed on the thin film transistor to be electrically connected to the thin film transistor.

The display diode may be an organic light emitting diode, but is not limited thereto. Any display diode may also be used.

In order to form the organic light emitting diode on the thin film transistor, a contact hole 130 is formed through the protective layer 115 to electrically connect the source or drain electrode to a first electrode 131 as shown in FIG. 7.

The first electrode 131 is one of the electrodes of the organic light emitting diode to be formed later and may include various conductive materials. The first electrode 131 may be a transparent electrode or a reflective electrode according to the organic light emitting diode to be formed later. The transparent electrode may be formed using ITO, IZO, ZnO, or In₂O₃, and the reflective electrode may be formed by forming a reflective layer using Ag, Mg, Al, Pt, Pd, Au, Ni, Nd, Ir, Cr, or any mixture thereof and forming ITO, IZO, ZnO, or In₂O₃ on the reflective layer.

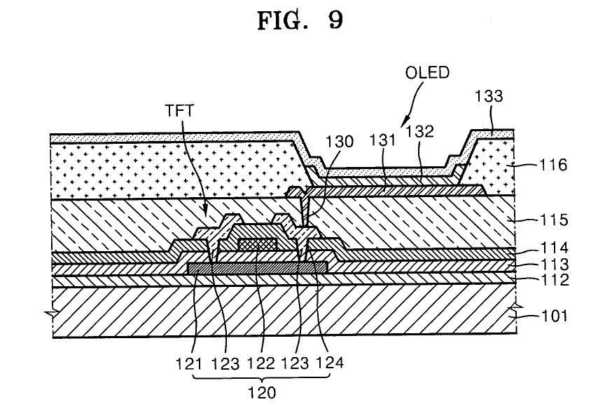

Then, as shown in FIG. 8, a pixel defining layer 116 that is patterned using an insulating material is formed on the first electrode 131 so as to expose at least a portion of the first electrode 131. Then, as shown in FIG. 9, an intermediate layer 132 including an emissive layer is formed on the exposed portion of the first electrode 131, and a second electrode 133 is formed on the intermediate layer 132 to be opposite to the first electrode 131, so as to prepare the organic light emitting diode.

Referring to FIG. 9, the intermediate layer 132 is patterned to correspond to each sub-pixel, i.e., the patterned first electrode 131. However, FIG. 9 is shown for convenience of description of the sub-pixel, the intermediate layer 132 may also be integrally formed with the intermediate layer 132 of an adjacent sub-pixel. The intermediate layer 132 may be modified in various forms. For example, one layer of the intermediate layer 132 may be formed to correspond to each sub-pixel and the other layers may be integrally formed with the intermediate layer 132 of an adjacent sub-pixel.

The intermediate layer 132 may include a low molecular weight or high molecular weight organic material. If a low molecular weight organic material is used, the intermediate layer 132 may be formed by stacking a hole injection layer (HIL), a hole transport layer (HTL), an organic emissive layer (EML), an electron transport layer (ETL), an electron injection layer (EIL), or the like to form a single or complex structure. Various organic materials such as copper phthalocyanine (CuPc), N,N′-di(naphthalene-1-yl)-N,N′-diphenyl-benzidine (NPB), tris-8-hydroxyquinoline aluminum (Alq3), or the like may be used. These low molecular weight organic materials may be formed by vacuum deposition using masks.

When a high molecular weight organic material is used, the intermediate layer 132 may generally include the HTL and the EML. Here, the HTL may be formed using PEDOT, and the EML may be formed using poly-phenylenevinylene (PPV) and polyfluorene by screen printing or inkjet printing.

The second electrode 133 may also be a transparent electrode or reflective electrode as the first electrode 131. The transparent electrode may include a layer including Li, Ca, LiF/Ca, LiF/Al, Al, Mg, or any compound thereof, and an auxiliary electrode or a bus electrode line formed on the layer which is formed of a material used to form a transparent electrode such as ITO, IZO, ZnO, or In₂O₃. In addition, the reflective electrode may be formed by blanket depositing Li, Ca, LiF/Ca, LiF/Al, Al, Mg, or any compound thereof.

Even though not shown in the drawings, an encapsulation member may further be formed.

Since the substrate on which the thin film transistor and the flexible display device described above are formed has a low outgassing amount, deterioration of the thin film transistor and the flexible display device may be prevented. The thin film transistor and the flexible display device have high reliability at high temperatures since the polymer substrate is not considerably deformed by heat due to a low thermal expansion coefficient.

Due to the polymer substrate having high thermal resistance, the polymer substrate is not considerably deformed by heat. Accordingly, the thin film transistor and flexible display device described above have high reliability.

While the present invention has been particularly shown and described with reference to exemplary embodiments thereof, it will be understood by those of ordinary skill in the art that various changes in form and details may be made therein without departing from the spirit and scope of the present invention as defined by the following claims.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A thin film transistor comprising:
a polymer substrate having a weight loss in the range of 0.000001 to 0.95% at a temperature in the range of 400 to 600° C.;
a semiconductor layer,
a gate insulating layer,
a gate electrode, and
a source and drain electrode.

2. The thin film transistor of claim 1, wherein the polymer substrate has a thermal expansion coefficient in the range of 1 to 50 ppm/° C.

3. The thin film transistor of claim 1, wherein the polymer substrate comprises a polyimide-based polymer.

4. The thin film transistor of claim 1, wherein the polymer substrate comprises a polyimide-based polymer formed by annealing a polyimide polymer at a temperature in the range of 150 to 550° C.

5. The thin film transistor of claim 1, wherein the semiconductor layer comprises a polycrystalline silicon layer.

6. A method of producing a thin film transistor, the method comprising:
preparing a polymer layer;
annealing the polymer layer at a temperature in the range of 150 to 550° C. to form a polymer substrate;
forming a semiconductor layer on the polymer substrate; and
forming a gate insulating layer, a gate electrode, and a source and drain electrode on the polymer substrate.

7. The method of claim 6, wherein the annealing comprises annealing the polymer layer at a temperature in the range of 150 to 550° C. for 5 minutes to 5 hours.

8. The method of claim 6, wherein the forming the semiconductor layer comprises:
forming an amorphous silicon layer;
dehydrogenating the amorphous silicon layer at a temperature in the range of 420 to 550° C.; and
crystallizing the dehydrogenated silicon layer by irradiating a laser beam to the dehydrogenated silicon layer.

9. The method of claim 8, wherein the dehydrogenating reduces the amount of hydrogen in the amorphous silicon layer to a concentration in the range of 0.000001 to 10%.

10. The method of claim 6, wherein the forming of the gate insulating layer is carried out by depositing tetraethyl orthosilicate (TEOS) at a temperature in the range of 350 to 450° C.

11. The method of claim 6, further comprising forming a barrier layer after annealing the polymer layer.

12. The method of claim 6, wherein the polymer substrate has a weight loss in the range of 0.000001 to 0.95% at a temperature in the range of 400 to 600° C.

13. The method of claim 6, wherein the polymer layer is formed of a polymer selected as having a weight loss in the range of 0.000001 to 0.95% at a temperature in the range of 400 to 600° C.

14. The method of claim 6, wherein the polymer substrate has a thermal expansion coefficient in the range of 1 to 50 ppm/° C.

15. The method of claim 6, wherein the polymer layer is formed of a polymer selected as having a thermal expansion coefficient in the range of 1 to 50 ppm/° C.

16. The method of claim 6, wherein the polymer substrate comprises a polyimide-based polymer.

17. The method of claim 6, wherein the semiconductor layer comprises a polycrystalline silicon layer.

18. A flexible display device comprising:
a thin film transistor prepared according to claim 1; and
a display diode formed on and electrically connected to the thin film transistor.

19. The flexible display device of claim 18, wherein the display diode is an organic light emitting diode.
